(19) United States
(12) Patent Application Publication
(10) Pub. No.: US 2019/0326257 A1
(43) Pub. Date: Oct. 24, 2019

(54) HIGH DENSITY FAN-OUT PACKAGING

(71) Applicants: Rahul Agarwal, Livermore, CA (US); Milind S. Bhagavat, Los Altos, CA (US); Lei Fu, Austin, TX (US)

(72) Inventors: Rahul Agarwal, Livermore, CA (US); Milind S. Bhagavat, Los Altos, CA (US); Lei Fu, Austin, TX (US)

(21) Appl. No.: 15/960,937

(22) Filed: Apr. 24, 2018

(51) Int. Cl. H01L 25/065; H01L 21/56; H01L 25/00; H01L 23/538; H01L 23/31; H01L 23/00; H01L 23/498

(52) U.S. Cl. CPC H01L 25/0655; H01L 2924/05442; H01L 25/50; H01L 23/5383; H01L 23/3135; H01L 24/08; H01L 23/3128; H01L 24/29; H01L 24/32; H01L 23/49827; H01L 24/83; H01L 2224/08235; H01L 2224/29188; H01L 2224/32225; H01L 2224/83896; H01L 2224/83488; H01L 21/561

(57) ABSTRACT

Various fan-out devices are disclosed. In one aspect, a semiconductor chip device is provided that includes a redistribution layer structure that has plural conductor structures and plural glass interlevel dielectric layers. A glass encapsulant layer is positioned on the redistribution layer structure. A first semiconductor chip and a second semiconductor chip are positioned in the glass encapsulant layer and electrically connected by at least some of the conductor structures. A cap layer is on the encapsulant layer.

### BACKGROUND OF THE INVENTION

A conventional type of multi-chip module includes two semiconductor chips mounted side-by-side on a carrier substrate or in some cases on an interposer (so-called “2.5D”) that is, in-turn, mounted on a carrier substrate. The semiconductor chips are flip-chip mounted to the carrier substrate and interconnected thereto by respective pluralities of solder joints. The carrier substrate is provided with plural electrical pathways to provide input/output pathways for the semiconductor chips both for inter-chip power, ground and signal propagation as well as input/output from the interposer itself. The semiconductor chips include respective underfill material layers to lessen the effects of differential thermal expansion due to differences in the coefficients of thermal expansion of the chips, the interposer and the solder joints.

One conventional variant of 2.5D interposer-based multi-chip modules uses a silicon interposer with multiple internal conductor traces for interconnects between two chips mounted side-by-side on the interposer. The interposer is manufactured with multitudes of through-silicon vias (TSVs) to provide pathways between the mounted chips and a package substrate upon which the interposer is mounted. The TSVs and traces are fabricated using large numbers of processing steps.

Another conventional multi-chip module technology is 2D wafer-level fan-out (or 2D WLFO). Conventional 2D WLFO technology is based on embedding die into a molded wafer, also called “wafer reconstitution.” The molded wafer is processed through a standard wafer level processing flow to create the final integrated circuit assembly structure. The active surface of the dies are coplanar with the mold compound, allowing for the “fan-out” of conductive copper traces and solder ball pads into the molded area using conventional redistribution layer (RDL) processing. Conventional 3D WLFO extends the 2D technology into multi-chip stacking where a second package substrate is mounted on the 2D WLFO.

Some other conventional designs use embedded interconnect bridges (EMIB). These are typically silicon bridge chips (but occasionally organic chiplets with top side only input/outputs) that are embedded in the upper reaches of a package substrate.

### BRIEF DESCRIPTION OF THE DRAWINGS

The foregoing and other advantages of the invention will become apparent upon reading the following detailed description and upon reference to the drawings in which:

FIG. 1 is a pictorial view of an exemplary semiconductor chip device that includes an exemplary fan-out chip combination;

FIG. 2 is a sectional view of FIG. 1 taken at section 2-2;

FIG. 3 is a portion of FIG. 2 shown at increased magnification;

FIG. 4 is a sectional view depicting exemplary multi-chip mounting on an RDL structure;

FIG. 5 is a sectional view like FIG. 4, but depicting exemplary chip thinning;

FIG. 6 is a sectional view like FIG. 5, depicting exemplary encapsulant layer application;

FIG. 7 is a sectional view like FIG. 6, but depicting exemplary encapsulant layer planarization;

FIG. 8 is a sectional view like FIG. 7, but depicting exemplary cap layer application;

FIG. 9 is a sectional view like FIG. 8, but depicting exemplary interposer wafer removal;

FIG. 10 is a sectional view like FIG. 9, but depicting exemplary RDL interconnect fabrication;

FIG. 11 is a portion of FIG. 10 shown at greater magnification;

FIG. 12 is a sectional view like FIG. 10, but depicting exemplary singulation;

FIG. 13 is a sectional view like FIG. 4, but depicting an alternate exemplary chip to RDL structure mounting;

FIG. 14 is a sectional view like FIG. 13, but depicting exemplary thinning of an interconnect substrate;

FIG. 15 is a sectional view like FIG. 14, but depicting exemplary I/O structure connections to the interconnect substrate; and

FIG. 16 is a sectional view depicting singulated parts from the aforementioned interconnect substrate.

### DETAILED DESCRIPTION

Chip geometries have continually fallen over the past few years. However the shrinkage in chip sizes has been accompanied by an attendant increase in the number of input/outputs for a given chip. This has led to a need to greatly increase the number of chip-to-chip interconnects for multi-chip modules. Current 2D and 3D WLFO have limited minimum line spacing, on the order of 2.0 μm/line and space. In addition, conventional WLFO techniques use multiple cured polyimide films to create the requisite RDL layers. These polyimide films tend to be mechanical stress, and thus warpage, sources and their relatively high bake temperatures can adversely impact other sensitive devices. Finally, conventional multi-chip fan out packages use solder bumping to electrically connect chips to polymer RDLs. Thus miniaturization is limited by prevailing bump connection techniques.

In accordance with one aspect of the present invention, a semiconductor chip device is provided that includes a redistribution layer structure that has plural conductor structures and plural glass interlevel dielectric layers. A glass encapsulant layer is positioned on the redistribution layer structure. A first semiconductor chip and a second semiconductor chip are positioned in the glass encapsulant layer and electrically connected by at least some of the conductor structures. A cap layer is on the encapsulant layer.

In accordance with another aspect of the present invention, a semiconductor chip device wafer is provided that includes a redistribution layer structure that has plural conductor structures and plural glass interlevel dielectric layers. A glass encapsulant layer is positioned on the redistribution layer structure. Plural semiconductor chips are positioned in the glass encapsulant layer. The semiconductor chips have conductor structures bumplessly connected to the conductor structures of the redistribution layer structure. Plural groups of two of the semiconductor chips are electrically connected to each other by the redistribution layer structure. A cap layer is on the encapsulant layer.

In accordance with another aspect of the present invention, a method of manufacturing is provided that includes mounting a first semiconductor chip and a second semiconductor chip on a redistribution layer structure. The redistribution structure includes plural conductor structures and plural glass interlevel dielectric layers. At least some of the conductor structures electrically connect the first semiconductor chip to the second semiconductor chip. A glass encapsulant layer is formed on the redistribution layer structure and over the first and second semiconductor chips. A cap layer is applied to the encapsulant layer.

In accordance with another aspect of the present invention, a semiconductor chip device is provided that includes an interconnect substrate that has plural through-substrate-vias and a redistribution layer structure positioned on the interconnect substrate. The redistribution layer structure includes plural conductor structures and plural glass interlevel dielectric layers. At least some of the conductor structures and the through-substrate-vias are electrically connected. A first semiconductor chip and a second semiconductor chip are positioned on the redistribution layer structure and electrically connected by at least some of the conductor structures. An insulating bonding layer is positioned between each of the first and second semiconductor chips and the redistribution layer structure. The insulating bonding layer includes a first glass layer bonded to a second glass layer.

In accordance with another aspect of the present invention, a method of manufacturing a semiconductor chip device is provided. The method includes positioning a redistribution layer structure on an interconnect substrate. The interconnect substrate has plural through-substrate-vias. The redistribution layer structure includes plural conductor structures and plural glass interlevel dielectric layers. At least some of the conductor structures and the through-substrate-vias are electrically connected. A first semiconductor chip and a second semiconductor chip are positioned on the redistribution layer structure. The first semiconductor chip and the second semiconductor chip are electrically connected with at least some of the conductor structures. The first semiconductor chip and the second semiconductor chip are bonded to the redistribution layer structure with an insulating bonding layer. The insulating bonding layer includes a first glass layer bonded to a second glass layer.

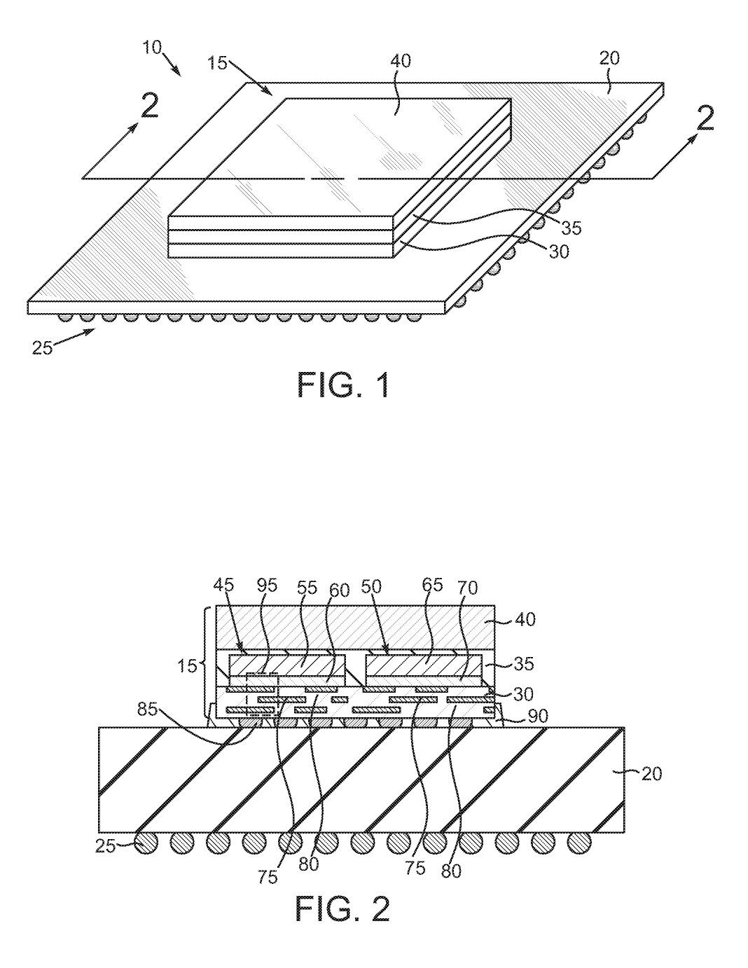

In the drawings described below, reference numerals are generally repeated where identical elements appear in more than one figure. Turning now to the drawings, and in particular to FIG. 1 which is a pictorial view of an exemplary semiconductor chip device 10. The semiconductor chip device 10 includes a fan-out semiconductor chip package 15, which can be mounted on a circuit board 20, which can be a system board, a circuit card, a semiconductor chip package substrate or otherwise. The circuit board 20 can interface electrically with some other electrical structure, such as another circuit board or other structure by way of plural interconnect structures 25, which in this arrangement constitute solder balls. However, the skilled artisan will appreciate that various types of interconnect structures could be used other than solder balls, such as, pins, land grid array structures or other types of interconnects. The fan-out semiconductor chip package 15 includes a RDL structure 30, an encapsulant layer 35 and a cap layer 40. One or more semiconductor chips (not visible in FIG. 1) are positioned in the encapsulant layer 35. As described in more detail below, the one or more semiconductor chips can be electronically connected to one another and to the circuit board 20 by way of the RDL structure 30.

Additional details of the semiconductor chip device 10 can be understood by referring now also to FIG. 2, which is a sectional view of FIG. 1 taken at section 2-2. As noted above in conjunction with FIG. 1, the encapsulant layer 35 at least partially encapsulates one or more semiconductor chips, two of which are shown and labeled 45 and 50, respectively. The semiconductor chip 45 includes a semiconductor substrate 55 and an interconnect structure 60, which can consist of plural layers of metallization and interlevel dielectric layers that are designed to be ohmically connected with various conductor structures of the RDL structure 30. The semiconductor chip 50 similarly includes a semiconductor substrate 65 and an interconnect structure 70, which can be like the semiconductor substrate 55 and the interconnect structure 60 just described. The semiconductor chips 45 and 50, and in particular the substrates 55 and 65 thereof, can be constructed of silicon, germanium, or other types of semiconductor materials. The encapsulant layer 35 is preferably constructed of glass(es) such as an oxide SiOx of silicon. It is anticipated that non-stoichiometric silicon oxide will be used in combination or not with various amounts of silicon dioxide. However, it is possible that a stoichiometric silicon dioxide layer can be used as well. An advantage of using SiOx for the encapsulant layer 35 over a conventional type of polymer molding material is that the oxide will have a CTE that is typically closer to the CTE's of the chips 45 and 50 and the RDL structure 30 than polymeric materials.

The semiconductor chips 45 and 50, and any others disclosed herein, can be any of a variety of integrated circuits. A non-exhaustive list of examples includes microprocessors, graphics processing units, application processing units that combines aspects of both, memory devices, an application integrated specific circuit or other. The semiconductor chip 45 is constructed with a physical device or “PHY” region, which has various internal and external conductor structures dedicated to the transmission of chip-to-chip signals, and a non-PHY region, which has conductor structures that are tailored more to the conveyance of power and ground and/or chip-to-circuit board signals. The semiconductor chip 50 similarly includes a PHY region and a non-PHY region that has the same functions as the PHY region and the non-PHY region of the semiconductor chip 45. As noted briefly above, the semiconductor chips 45 and 50 are connected electrically by way of the RDL structure 30.

The RDL structure 30 consists of plural layers of conductor structures 75, such as traces, pads, vias and other types of conductor structures suitable for RDL fabrication, and plural interlevel dielectric layers 80. The conductor structures 75 can be constructed of copper, aluminum, gold, platinum, palladium, combinations of such or other conductors, and be fabricated using well-known material deposition techniques, such as, plating, sputtering, chemical vapor deposition, combinations of these or the like and patterned as necessary using well-known photolithography and directional etching techniques. Significantly, the conductor structures 30 are fabricated with fine line widths and spacings, on order of 1.0 μm or less. Fine line spacing and more than two levels of conductors can provide high density interconnect pathways between the chips 45 and 50 in a bumpless process. Some of the conductor structures 75 can be devoted to chip-to-chip communications and others can be used for power and ground both chip-to-chip and/or chip-to-board. The interlevel dielectric layers 80 can be constructed of glass(es) such as SiOx or other types of interlevel dielectric layer materials. The conductor structures 75 not only provide electrical pathways from the chips 45 and 50 to the circuit board 20 but also chip-to-chip connections, particularly between the PHY regions of each of the chips 45 and 50. The RDL structure 30 is electrically connected to the circuit board 20 by way of plural interconnects 85, which may be solder bumps, conductive pillars or other types of interconnects. If composed of solder, the interconnects 85 and the interconnects 25 can be composed of various well-known solder compositions, such as tin-silver, tin-silver-copper or others.

The circuit board 20 can be organic or ceramic and single, or more commonly, multilayer. To cushion against the effects of mismatched coefficients of thermal expansion, an underfill material 90 can be positioned between the RDL structure 30 and the upper surface of the circuit board 20 and can extend laterally beyond the left and right edges (and those edges not visible) of the RDL structure 30 as desired. The underfill material 90 can be composed of well-known polymeric underfill materials.

The cap layer 40 is advantageously constructed of silicon, another type of semiconductor or even a glass material. The purpose of the cap layer 40 is to facilitate certain process steps leading to the singulation of the combination of the chips 45 and 50 from an overall larger workpiece, and to provide a material that has a CTE that again is preferably close to the CTE of the chips 45 and 50. The cap layer 40 has a relatively planar upper surface to facilitate the subsequent optional placement of a heat spreader thereon.

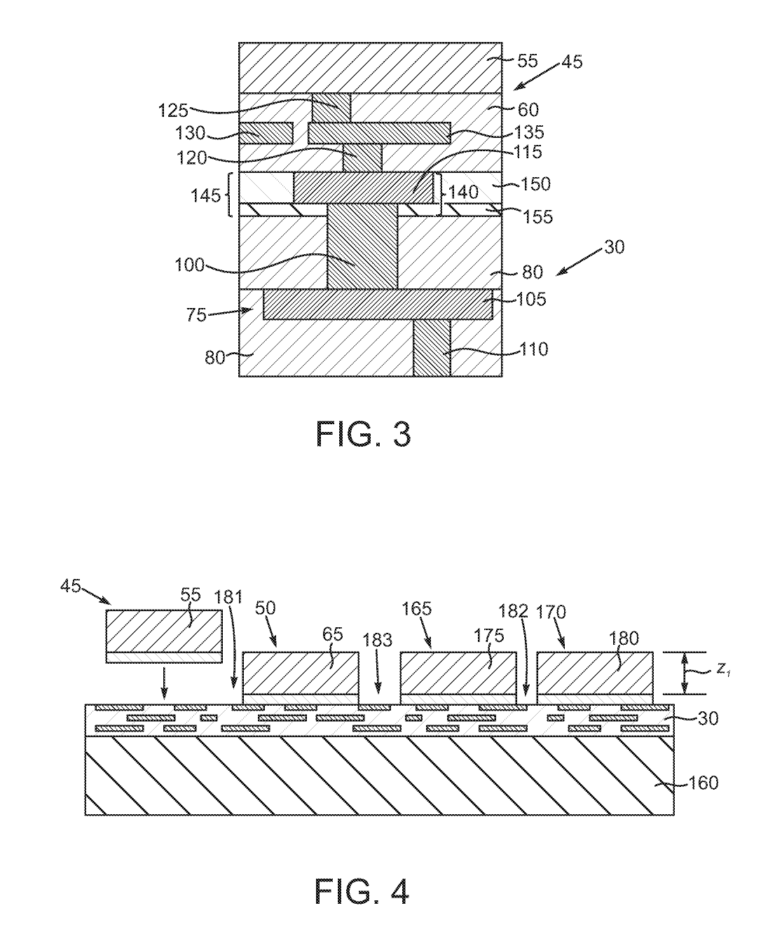

Some additional details of the RDL structure 30 may be understood by referring now also to FIG. 3, which is the portion of FIG. 2 circumscribed by the small dashed rectangle 95 shown at greater magnification. The RDL structure 30 includes multiple interlevel dielectric layers 80 and layers of conductor structures 75 (traces, vias and pads, etc.). A bond pad 100, a trace 105 and a via 110 are depicted, but of course there can be many more such structures. The interconnect structure 60 of the semiconductor chip 45 similarly includes plural metallization and interlevel dielectric layers. A bond pad 115, vias 120 and 125 and traces 130 and 135 are depicted, but of course there can be many more such structures. The chip 45 is joined to the RDL structure 30 using a bumpless oxide hybrid bonding technique. In this regard, an interconnect 140 between the semiconductor chip 45 and the RDL structure 30 is made up of a metallurgical bond between the bond pads 100 and 115. In addition, an insulating bonding layer 145 joins the chip 45 to the RDL structure 30 and consists of glass layer 150, such as SiOx, of the semiconductor chip 45 and another glass layer 155, such as silicon oxynitride, of the RDL structure 30. The bond pad 115 is positioned in the glass layer 150 and the bond pad 100 projects up through the glass layer 155. The bond pad 100 and the bond pad 115 are metallurgically bonded by way of an anneal process. In this regard, the semiconductor chip 45 is brought down or otherwise positioned on the RDL structure 30 so that the glass layer 150 is on or in very close proximity to the silicon oxynitride layer 155 and the bond pad 115 is on or in very close proximity to the bond pad 100. Thereafter, an anneal process is performed, which produces a transitory thermal expansion of the bond pads 100 and 115 bringing those structures into physical contact and causing them to form a metallurgical bond that persists even after the chip 45 and RDL structure 30 are cooled and the bond pads 100 and 115 contract thermally. Copper performs well in this metal bonding process, but other conductors could be used. There is also formed an oxide/oxynitride bond between the glass layer 150 and the glass layer 155.

An exemplary process to fabricate the semiconductor chip device 10 depicted in FIGS. 1 and 2 can be understood by referring now to FIGS. 4, 5, 6, 7, 8, 9, 10, 11 and 12 and initially to FIG. 4. FIG. 4 depicts a sectional view of a portion of an interposer wafer 160 upon which the RDL structure 30 has been fabricated. The semiconductor chips 45 and 50 and two other semiconductor chips 165 and 170 of what may total scores or more of such chips. The semiconductor chips 45, 50, 165 and 170 can be manufactured en masse in semiconductor wafers (not shown), which are subsequently singulated to yield the individual semiconductor chips 45, 50, 165 and 170. During these fabrication processes, the various electronic structures that include transistors, capacitors, inductors and whatever other logic elements and circuit structures that are appropriate for the chips 45, 50, 165 and 170 can be constructed. The semiconductor chips 45, 50, 165 and 170 are subjected to testing so that they are identified as known good die before they are mounted on the RDL structure 30.

The RDL structure 30 is fabricated on an interposer wafer 160 using a multitude of well-known metal fabrication and interlevel dielectric layer fabrication techniques, such as plasma enhanced chemical vapor deposition for oxide or other insulating materials, plating, sputtering or other metal material deposition techniques followed by lithographic patterning by way of masking, suitable etching, etc. The interposer wafer 160 is in an exemplary embodiment composed of silicon but could also be composed of glass or other semiconductor materials. Note that only a portion of the interposer wafer 160 is depicted. One advantage of fabricating the RDL structure 30 on the interposer wafer 160 separate and apart from the initial fabrication of the semiconductor chips 45, 50, 165 and 170, is that the RDL structure 30 can more extensive than the footprints of the chips the chips 45, 50, 165 and 170. The semiconductor chips 45, 50, 165 and 170 are fabricated separate and apart from the RDL structure 30, typically in a wafer level process. The semiconductor chips 45, 50, 165 and 170 are mounted to the RDL structure 30 using the oxide hybrid bonding technique described above in conjunction with FIG. 3. The gaps 181 and 182 between pairs of chips 45 and 50 and 165 and 170 can be quite small, on the order of 20 to 50 μm and the gap 183 between adjacent chips 50 and 165 of different pairs can be somewhat larger, on the order of 50 to 100 Note that at this point, the semiconductor chips 45, 50, 165 and 170 and in particular their semiconductor substrates 55, 65, 175 and 180 may or may not have not undergone a thinning process, but either way have some initial z-height z₁.

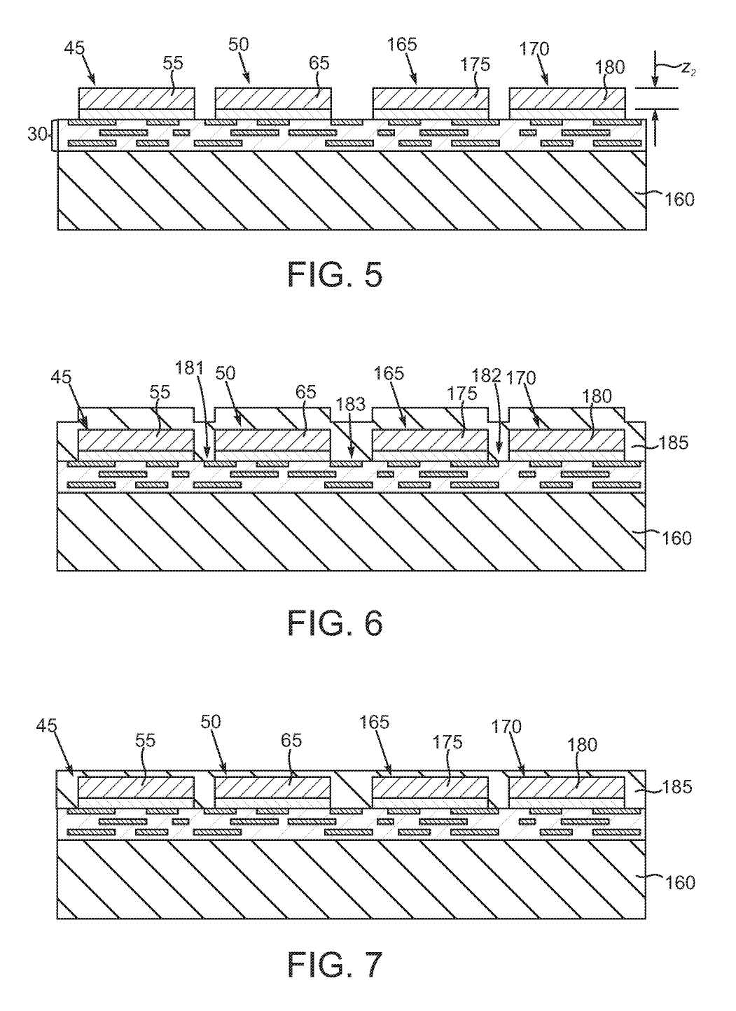

Next and as depicted in FIG. 5, the semiconductor chips 45, 50, 165 and 170 undergo a thinning process by way of grinding or otherwise to reduce the height of the semiconductor substrates 55, 65, 175 and 180 of the semiconductor chips 45, 50, 165 and 170 to some shorter height z₂. This grinding process also facilitates a planarization of the chips 45, 50, 165 and 170. The RDL structure 30 and the interposer wafer 160 are relatively unaffected by this grinding process. In an alternative process, thinning is not required at this point.

Next and as shown in FIG. 6, an encapsulant material layer 185 is deposited over the semiconductor chips 45, 50, 165 and 170, including the substrates 55, 65, 175 and 180 thereof, and the otherwise exposed portions of the RDL structure 30. The encapsulant layer 185 will, through subsequent processes, be patterned into encapsulant layer 35 shown in FIG. 2 and other such layers for the other chips on the interposer wafer 160. As shown in FIG. 6, the encapsulant layer 185 is not planar due to the gaps 181, 182 and 183 between the chips 45, 50, 165 and 170.

As shown in FIG. 7, the encapsulant layer 185 is thinned, preferably by CMP, to leave a thin portion thereof above the semiconductor chips 45, 50, 165 and 170, and particularly the semiconductor substrates 55, 65, 175 and 180 thereof. The interposer wafer 160 provides mechanical support and protection during both the grinding and CMP processes just described.

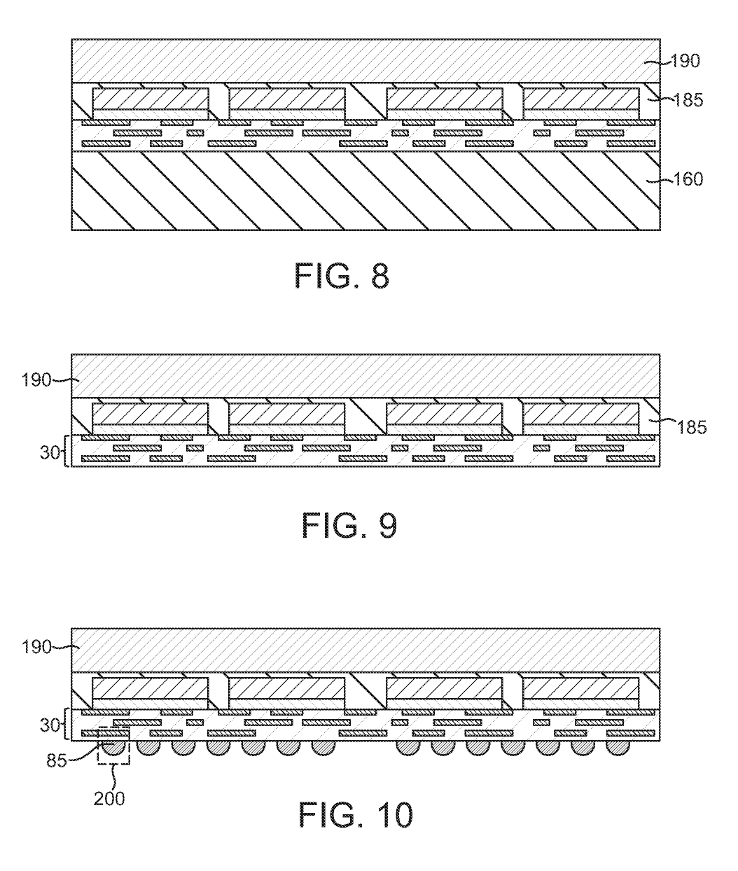

Following the thinning and planarization of the encapsulant layer 185 shown in FIG. 7, a cap wafer 190 is bonded to the encapsulant layer 185 as depicted in FIG. 8. The cap wafer 190 will, following singulation to be described below, be separated into individual cap layers, such as a cap layer 40 depicted in FIG. 2, for all of the semiconductor chips 45, 50, 165 and 170. The cap wafer 190 is preferably secured to the encapsulant layer 185 by way of an oxide hybrid bonding of the type described above in conjunction with FIG. 3 but without the metallurgical anneal bonding. Instead, the bonding is by way of an oxide to oxynitride bonding.

The cap wafer 190 is bonded onto the encapsulant layer 185 with the interposer wafer 160 in place. However, following the mounting of the cap wafer 190, the interposer wafer 160 is removed as shown in FIG. 9 by a combination of a grinding process and an etch back. The grinding process removes the majority of the interposer wafer 160 and then a subsequent etch back process is used to expose portions of the lowermost metallization layer of the RDL structure 30 in preparation for attachment of the interconnects, such as the interconnects 85 depicted in FIG. 2. The etch back is preferably performed as a dry etch with plasma enhancement. Directional etching is desired in order to establish relatively vertical sidewalls of any openings leading to the lower most metallization of the RDL structure 30.

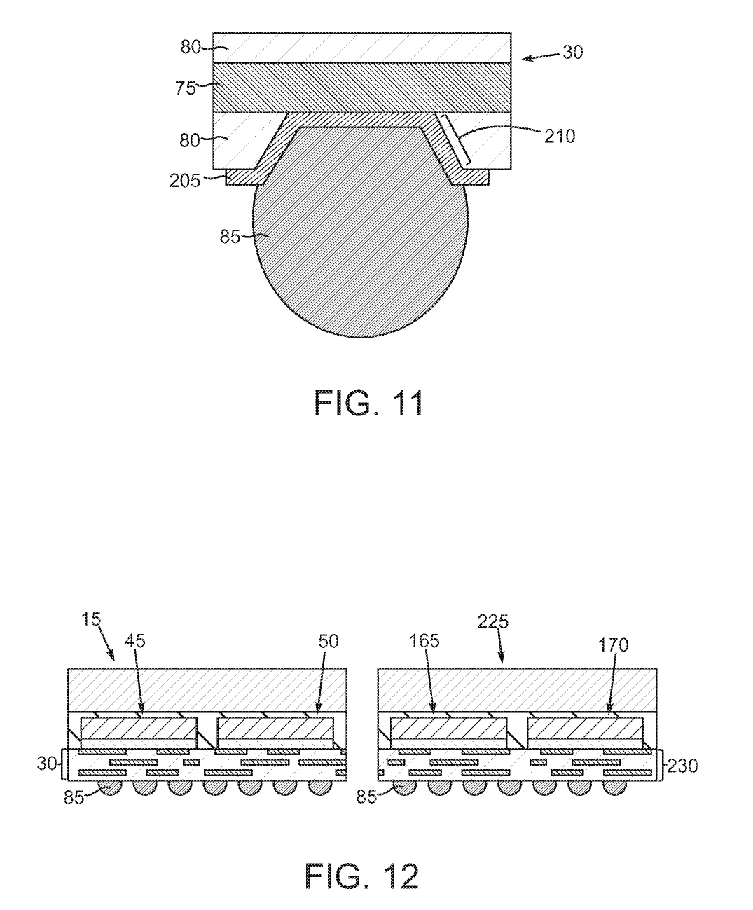

Next as shown in FIG. 10, the interconnects 85 are attached to the RDL structure 30 with the cap wafer providing support. The mounting can be accompanied by or performed in conjunction with the fabrication of underbump metallization (UBM). Note the location of the small dashed rectangle 200 in FIG. 10. That rectangle 200 encompasses one of the interconnects 85. That portion is shown at greater magnification in FIG. 11. As shown in FIG. 11, a UBM structure 205 can be fabricated prior to attachment of the interconnect 85. The UBM structure 205 can be deposited as a laminate of multiple layers such as TiN, copper, nickel, gold, vanadium or other UBM structure materials on the lowermost dielectric layer 80 of the RDL structure 30. Initially, an opening 210 is created in the lowermost dielectric layer 80, which can be oxide or even a polymer, such as polyimide or benzocyclobutene, of the RDL structure 30 leading to the lower most metallization layer 75 of the RDL structure 30 using the etch back process described above. Subsequent to the deposition of multiple conductor layers for the UBM structure 205, a suitable lithographic process is performed to etch define the individual UBM structures 205. Thereafter, the interconnect 85 can be mounted to the UBM structure 205 and a reflow performed to establish the requisite metallurgical bonding.

Subsequent to the attachment of the interconnects 85, the cap wafer 190 and individual groupings of semiconductor chips 45 and 50 and 165 and 170 undergo singulation to yield the fan out package 15 and another fan out package 225, which consists of the semiconductor chips 165 and 170 and their associated RDL structure 230. At this point, the fan-out packages 15 and 225 can be mounted to circuit boards, such as the circuit board 20 depicted in FIGS. 1 and 2, using well-known mounting and reflow processes.

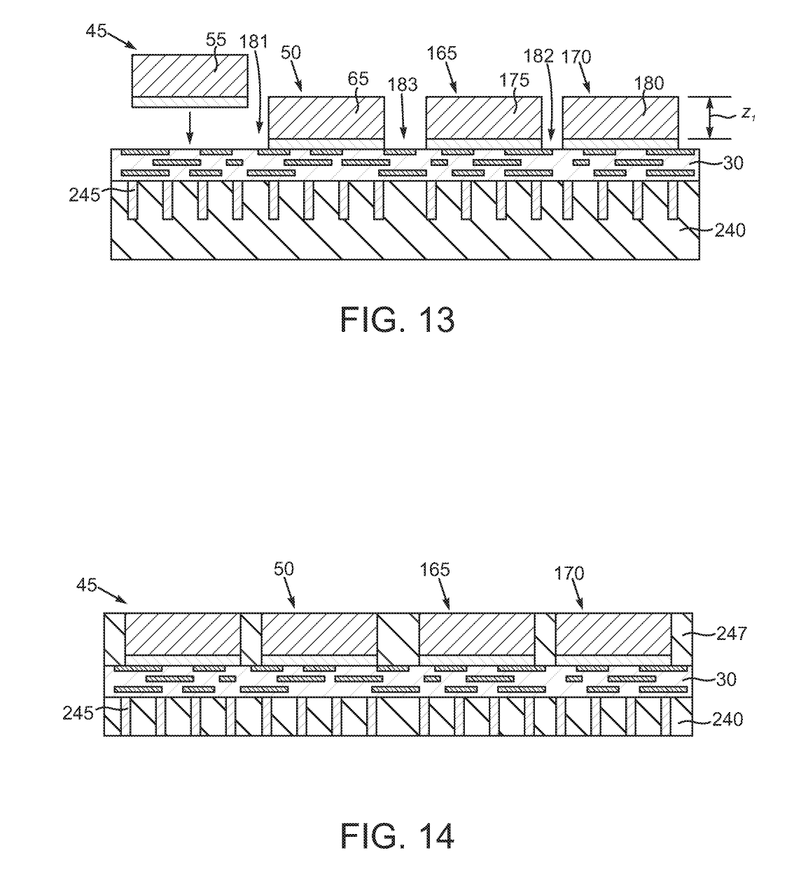

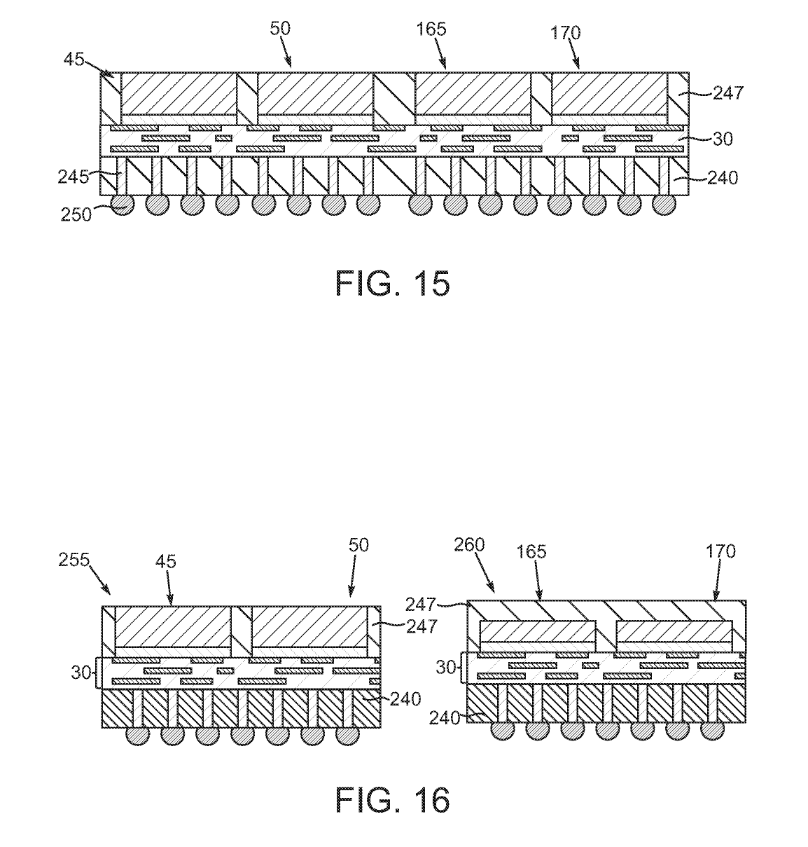

An alternate exemplary process flow can be used to fabricate semiconductor chip devices using the aforementioned bumpless oxide hybrid bonding techniques but while also providing for RDL structure to exterior device interconnections by way of through substrate vias. This exemplary process flow may be understood by referring now to FIGS. 13, 14, 15 and 16. FIG. 13 is a sectional view like FIG. 4, but with some important exceptions to be described presently. Here, in lieu of using a carrier wafer 160 shown in FIG. 4, the RDL structure 30 is fabricated on an interconnect substrate 240, which can be a wafer and which has been processed to include plural through-substrate-vias 245. At this stage, the interconnect substrate 240 has not been thinned to reveal the through-substrate-vias (TSV) 245. The TSVs 245 are electrically connected to various conductor structures of the RDL structure 30. The semiconductor chips 45, 50, 165 and 170 are mounted on, and electrically and mechanically connected to the RDL structure 30 using the aforementioned bumpless oxide hybrid bonding techniques. The TSVs 245 can be constructed of well-known TSV material such as copper, aluminum, gold, platinum, palladium, combinations of such or other conductors, and be fabricated using well-known material deposition techniques, such as, plating, sputtering, chemical vapor deposition, combinations of these or the like. If desired, well-known liner layers of SiOx or other materials can be used. The interconnect substrate 240 can be constructed of silicon, germanium, other types of semiconductors, or the like. The gaps 181 and 182 between pairs of chips 45 and 50 and 165 and 170 can be quite small, on the order of 20 to 50 μm and the gap 183 between adjacent chips 50 and 165 of different pairs can be somewhat larger, on the order of 50 to 100 μm. Note that at this point, the semiconductor chips 45, 50, 165 and 170 and in particular their semiconductor substrates 55, 65, 175 and 180 have not undergone a thinning process and thus have some initial z height, z₁.

Next and as shown in FIG. 14, a molding layer 247 is molded on the RDL structure 30 to temporarily encase the chips 45, 50, 165 and 170. Various molding materials can be used. Two commercial variants are Sumitomo EME-G750 and G760. The molding layer 247 is subjected to a grinding process to flatten it and reveal the tops of the chips 45, 50, 165 and 170. The molding layer 247 provides structural support during a subsequent process to reveal the TSVs 245. With the molding layer 247 in place, the interconnect substrate 240 undergoes a thinning process to reveal the TSVs 245. This thinning process can be performed in a variety of ways. In one so-called “hard reveal” technique, a grinding process is used to expose the TSVs 245 followed by an etch back of a small amount of the substrate 240 (silicon or otherwise), followed by a thin oxide growth or deposition or a thin silicon nitride deposition by CVD and again followed by a chemical mechanical planarization in order to finalize the through-chip via reveal. In another technique involving a so-called “soft reveal,” the interconnect substrate 240 is subjected to a grinding process to just above the tops of the TSVs 245, followed by an etch back and an oxide and/or nitride deposition and ultimately a chemical mechanical polishing (CMP) step to perform the through-chip via reveal. This second technique avoids exposing the substrate 240 to loose copper or other metal particles that can be liberated during a hard reveal.

With the TSVs 245 revealed, suitable I/O structures 250 can be connected to the TSVs 245. The I/Os 250 can be solder bumps, balls or other types of interconnect structures. At this point, the semiconductor chips 45, 50, 165 and 170 and the molding layer 247 can undergo a thinning process if desired.

Next and as shown in FIG. 16, singulation can be performed to yield a semiconductor chip device 255 that includes the semiconductor chips 45 and 50, a portion of the RDL structure 30 and a portion of the interconnect substrate 240, and a semiconductor chip device 260 that includes the semiconductor chips 165 and 170, another portion of the RDL structure 30 and another portion of the substrate 245 and so on for the remainder of the interconnect 240. Of course, the semiconductor chip device 255 and 260 can be mounted to another device such as the circuit board 20 depicted in FIGS. 1 and 2. In this way, the semiconductor chip devices 255 and 260 can provide large numbers of small scale interconnects between chips 45 and 50 and the RDL 30 by way of the aforementioned hybrid bonding technique but with the molding layer 247.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents and alternatives falling within the spirit and scope of the invention as defined by the following appended claims.

What is claimed is:

1. A semiconductor chip device, comprising:
a redistribution layer structure including plural conductor structures and plural glass interlevel dielectric layers;
a glass encapsulant layer positioned on the redistribution layer structure;
a first semiconductor chip and a second semiconductor chip positioned in the glass encapsulant layer and electrically connected by at least some of the conductor structures; and
a cap layer on the encapsulant layer.

2. The semiconductor chip device of claim 1, comprising an insulating bonding layer positioned between and bonding the first semiconductor chip and the second semiconductor chip to the redistribution layer structure, the insulating bonding layer including a first glass layer bonded to a second glass layer.

3. The semiconductor chip device of claim 2, wherein the first glass layer comprises silicon oxide and the second glass layer comprises silicon oxynitride.

4. The semiconductor chip device of claim 1, wherein each of the first semiconductor chip and the second semiconductor chip includes conductor structures bumplessly bonded to some of the conductor structures of the redistribution layer structure.

5. The semiconductor chip device of claim 1, wherein the redistribution layer structure comprises plural interconnects to electrically connect to another device.

6. The semiconductor chip device of claim 1, comprising a circuit board, the redistribution layer structure being mounted on the circuit board.

7. A semiconductor chip device wafer, comprising:
a redistribution layer structure including plural conductor structures and plural glass interlevel dielectric layers;
a glass encapsulant layer positioned on the redistribution layer structure;
plural semiconductor chips positioned in the glass encapsulant layer, the semiconductor chips having conductor structures bumplessly connected to the conductor structures of the redistribution layer structure, plural groups of two of the semiconductor chips being electrically connected to each other by the redistribution layer structure; and
a cap layer on the encapsulant layer.

8. The semiconductor chip device wafer of claim 7, comprising an insulating bonding layer positioned between and bonding the semiconductor chips to the redistribution layer structure, the insulating bonding layer including a first glass layer bonded to a second glass layer.

9. The semiconductor chip device wafer of claim 8, wherein the first glass layer comprises silicon oxide and the second glass layer comprises silicon oxynitride.

10. The semiconductor chip device wafer of claim 8, wherein the redistribution layer structure comprises plural interconnects to electrically connect to another device.

11. The semiconductor chip device wafer of claim 10, wherein the interconnects comprise solder structures.

12. The semiconductor chip device wafer of claim 7, wherein the cap layer comprises a silicon layer.

13. A method of manufacturing, comprising:
mounting a first semiconductor chip and a second semiconductor chip on a redistribution layer structure, the redistribution structure including plural conductor structures and plural glass interlevel dielectric layers, at least some of the conductor structures electrically connecting the first semiconductor chip to the second semiconductor chip;
forming a glass encapsulant layer on the redistribution layer structure and over the first and second semiconductor chips; and
applying a cap layer on the encapsulant layer.

14. The method of claim 13, wherein the mounting comprises forming an insulating bonding layer between and bonding the first semiconductor chip and the second semiconductor chip to the redistribution layer structure, the insulating bonding layer including a first glass layer bonded to a second glass layer.

15. The method of claim 14, wherein the first glass layer comprises silicon oxide and the second glass layer comprises silicon oxynitride.

16. The method of claim 14, comprising annealing to bond the first glass layer to the second glass layer and to metallurgically bond conductor structures of the first semiconductor chip and conductor structures of the second semiconductor chip to some of the conductor structures of the redistribution layer structure.

17. The method of claim 13, comprising wherein each of the first semiconductor chip and the second semiconductor chip includes conductor structures bumplessly bonding conductor structures of the first semiconductor chip and conductor structures of the second semiconductor chip to some of the conductor structures of the redistribution layer structure.

18. The method of claim 13, comprising forming plural interconnects on the redistribution layer structure to electrically connect to another device.

19. The method of claim 13, comprising mounting the redistribution layer structure on a circuit board.

20. The method of claim 13, wherein the redistribution layer structure is mounted on a wafer prior to mounting the first and second semiconductor chips.

21. A semiconductor chip device, comprising:
an interconnect substrate having plural through-substrate-vias;
a redistribution layer structure positioned on the interconnect substrate and including plural conductor structures and plural glass interlevel dielectric layers, at least some of the conductor structures and the through-substrate-vias being electrically connected;
a first semiconductor chip and a second semiconductor chip positioned on the redistribution layer structure and electrically connected by at least some of the conductor structures; and
an insulating bonding layer positioned between each of the first and second semiconductor chips and the redistribution layer structure, the insulating bonding layer including a first glass layer bonded to a second glass layer.

22. The semiconductor chip device of claim 21, wherein the first glass layer comprises silicon oxide and the second glass layer comprises silicon oxynitride.

23. A method of manufacturing a semiconductor chip device, comprising:
positioning a redistribution layer structure on an interconnect substrate, the interconnect substrate having plural through-substrate-vias, the redistribution layer structure including plural conductor structures and plural glass interlevel dielectric layers, at least some of the conductor structures and the through-substrate-vias being electrically connected;
positioning a first semiconductor chip and a second semiconductor chip on the redistribution layer structure and electrically connecting the first semiconductor chip and the second semiconductor chip with at least some of the conductor structures; and
bonding the first semiconductor chip and the second semiconductor chip to the redistribution layer structure with an insulating bonding layer, the insulating bonding layer including a first glass layer bonded to a second glass layer.

24. The method of claim 23, wherein the first glass layer comprises silicon oxide and the second glass layer comprises silicon oxynitride.
